(19) United States
(12) Patent Application Publication
(10) Pub. No.: US 2008/0179740 A1
(43) Pub. Date: Jul. 31, 2008

(54) PACKAGE SUBSTRATE, METHOD OF FABRICATING THE SAME AND CHIP PACKAGE

(75) Inventor: Guo-Cheng Liao, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/017,542

(22) Filed: Jan. 22, 2008

(30) Foreign Application Priority Data
Jan. 25, 2007 (TW) 96102832

(51) Int. Cl. H01L 23/488; H05K 3/00; H05K 1/00

(52) U.S. Cl. 257/738; 174/267; 29/846; 257/E23.023

(57) ABSTRACT

A package substrate, including a base layer, a surface circuit layer, a plurality of conductive bumps, and a patterned solder mask layer, is provided. The surface circuit layer having a plurality of bonding pads is disposed on a surface of the base layer. The conductive bumps are disposed on the bonding pads individually. The patterned solder mask layer is disposed on the surface of the base layer and outside a corresponding region occupied by the conductive bumps, so as to expose the conductive bumps. In addition, a method of fabricating the package substrate and a chip package structure employing the package substrate are also provided.

### CROSS-REFERENCE TO RELATED APPLICATION

This application claims the priority benefit of Taiwan application serial no. 96102832, filed on Jan. 25, 2007. The entirety of the above-mentioned patent application is hereby incorporated by reference herein and made a part of this specification.

### BACKGROUND OF THE INVENTION

1. Field of the Invention

The present invention relates to a circuit board, a method of fabricating the same, and a semiconductor device. More particularly, the present invention relates to a package substrate, a method of fabricating the same, and a chip package structure.

2. Description of Related Art

In flip-chip bonding technology commonly seen in semiconductor packaging industry, a chip bump is often fabricated on each chip pad, which is formed on an active surface of a wafer, such that the chip bump serves as an intermedium for electrically connecting a chip, which is formed by sawing the wafer, to a carrier. Since the flip-chip bonding technology employs a method of defining an area array by disposing the chip bumps on the active surface of the chip, the flip-chip bonding technology is suitable for a chip package structure of high contact count and high contact density. Additionally, in comparison with a wire bonding technology, the chip bumps in the flip-chip bonding technology provide a shorter signal transmission path between the chip and the carrier, thereby enhancing the electrical performance of the chip package structure.

In a conventional flip-chip package, a controlled collapse chip connection (C4) technology, in which the bumps are self-aligned and the distance between the chip and a package substrate remains consistent, is utilized. Since the package substrate is usually a polymer substrate made of organic materials and is not of high heat resistance, it is not allowed to have an excessively-high process temperature at which a reflow process is carried out for bonding the chip to the polymer substrate. As such, a substrate bump made of solder materials having a relatively low melting point is formed on each bonding pad of the package substrate in advance. When undergoing the aforementioned reflow process, the substrate bump melts and encompasses the corresponding un-melted chip bump (having a relatively high melting point). A joint bump is thus formed, achieving the goal of electrical connection between the chip and the package substrate.

Currently, the methods of forming the substrate bumps having the relatively low melting point on the bonding pads of the package substrate include a screen-printing method, an electroplating method, and so forth. Please refer to FIG. 1, which is a schematic cross-sectional view of a conventional package substrate. As chip circuit layout progresses toward high integration, pitches d1 between adjacent bonding pads 110 of a package substrate 100 are correspondingly shortened, such that distribution density of the bonding pads 110 is increased as well.

If substrate bumps 130 are formed by performing the screen-printing method, the high density requirement of the substrate bump 130 cannot be satisfied due to limitations on the fabrication of a printing screen and printing solder materials. Moreover, the overly-short pitches d1 between the bonding pads 110 easily give rise to erroneous bridging of substrate bumps 130, thus reducing the manufacturing yield. Therefore, the electroplating method is proposed for forming the substrate bumps, such that the high integration requirement for fabricating the substrate can be satisfied.

However, as alignment errors from exposure of photoresist are taken into account, a certain area needs to be retained outside an opening 122 of a solder mask layer 120 in a conventional manufacturing process of the substrate bumps 130 on the package substrate 100. As such, the substrate bumps 130 cover a portion of the solder mask layer 120. Consequently, when a heating process is performed on the package substrate 100 or when the flip-chip bonding technology is actually employed with use of the package substrate 100, bonding bumps may be affected by stresses of the underlying solder mask layer 120 and then be peeled from or separated from the bonding pads 110 due to the fact that the coefficient of thermal expansion (CTE) of the solder mask layer 120 and that of the package substrate 110 are not matched. Therefore, the reliability of the chip package structure is impaired.

### SUMMARY OF THE INVENTION

The present invention is directed to a package substrate on which substrate bumps of high distribution density are disposed. The package substrate is applicable in a chip package technology requiring high integration. Moreover, the package substrate is conducive to improving the reliability of a chip package structure.

The present invention is further directed to a method of fabricating a package substrate. The method is suitable for forming substrate bumps of high distribution density and has a higher manufacturing yield.

The present invention is further directed to a chip package structure employing said package substrate. The chip package structure is able to comply with the high integration requirement for packaging and has a higher reliability.

To describe the present invention in specific details, a package substrate including a base layer, a surface circuit layer, a plurality of conductive bumps, and a patterned solder mask layer is provided herein. The surface circuit layer having a plurality of bonding pads is disposed on a surface of the base layer. The conductive bumps are disposed on the bonding pads individually. The patterned solder mask layer is disposed on the surface of the base layer and outside a corresponding region occupied by the conductive bumps, so as to expose the conductive bumps.

According to an embodiment of the present invention, the patterned solder mask layer is further disposed outside a corresponding region occupied by the bonding pads, so as to expose the bonding pads.

According to an embodiment of the present invention, the conductive bumps include a plurality of metal posts.

According to an embodiment of the present invention, the material used for the conductive bumps includes copper.

According to an embodiment of the present invention, the base layer has a chip bonding region in which the bonding pads are arranged in arrays. In addition, the chip bonding region is exposed by the patterned solder mask layer.

According to an embodiment of the present invention, the package substrate further includes an organic solderability preservative (OSP) layer disposed on surfaces of the conductive bumps and surfaces of the bonding pads.

According to an embodiment of the present invention, the base layer includes a plurality of dielectric layers and at least an inner circuit layer disposed between two adjacent dielectric layers.

The present invention further provides a method of fabricating a package substrate. The method includes the following steps. A base layer is provided at first. An electroplating seed layer is then formed on a surface of the base layer. Thereafter, the surface of the base layer is covered by a first patterned mask layer, which exposes a portion of the electroplating seed layer. Afterwards, an electroplating process is performed to form a surface circuit layer on the electroplating seed layer, which is exposed by the first patterned mask layer. Here, the surface circuit layer includes a plurality of bonding pads. Next, the first patterned mask layer and the surface circuit layer are covered by a second patterned mask layer exposing at least a portion of each of the bonding pads. The electroplating process is then performed to form a plurality of conductive bumps on the bonding pads exposed by the second patterned mask layer. After that, the first patterned mask layer and the second patterned mask layer are removed. Thereafter, the electroplating seed layer outside the surface circuit layer is removed. Finally, a patterned solder mask layer is formed on the surface of the base layer, and the patterned solder mask layer exposes the conductive bumps.

According to another embodiment of the present invention, the method of forming the patterned solder mask layer includes the following steps. First, a solder mask material layer is formed on the surface of the base layer, such that the solder mask material layer covers the surface circuit layer and the conductive bumps. After that, a patterning process is performed on the solder mask material layer, so as to remove the solder mask material layer corresponding to the conductive bumps. Besides, the patterning process includes performing a photolithography process on the solder mask material layer.

According to another embodiment of the present invention, the patterned solder mask layer further exposes the bonding pads in the method of fabricating the package substrate.

According to another embodiment of the present invention, the base layer has a chip bonding region in which the bonding pads are arranged in arrays. Moreover, the patterned solder mask layer further exposes the chip bonding region in the method of fabricating the package substrate.

According to another embodiment of the present invention, the method of fabricating the package substrate further includes applying a surface treatment to the conductive bumps and the bonding pads after the formation of the patterned mask layer. Additionally, the surface treatment includes forming an OSP layer on surfaces of the conductive bumps and surfaces of the bonding pads.

According to another embodiment of the present invention, the first patterned mask layer or the second patterned mask layer includes a dry film photoresist.

The present invention further provides a chip package structure including a base layer, a surface circuit layer, a plurality of conductive bumps, a patterned solder mask layer, a chip, and a plurality of chip bumps. The surface circuit layer having a plurality of bonding pads is disposed on a surface of the base layer. The conductive bumps are disposed on the bonding pads individually. The patterned solder mask layer is disposed on the surface of the base layer and outside a corresponding region occupied by the conductive bumps, so as to expose the conductive bumps. The chip is disposed on the surface circuit layer, and a plurality of chip pads is disposed on a surface of the chip that faces the surface circuit layer. The chip bumps are correspondingly connected between the chip pads and the conductive bumps.

According to still another embodiment of the present invention, the patterned solder mask layer is further disposed outside a corresponding region occupied by the bonding pads, so as to expose the bonding pads.

According to still another embodiment of the present invention, the conductive bumps include a plurality of metal posts.

According to still another embodiment of the present invention, the material used for the conductive bumps includes copper.

According to still another embodiment of the present invention, the base layer has a chip bonding region in which the bonding pads are arranged in arrays. In addition, the chip bonding region is exposed by the patterned solder mask layer.

According to still another embodiment of the present invention, the chip package structure further includes a plurality of solder balls disposed at a side of the base layer that is away from the chip.

According to still another embodiment of the present invention, the base layer includes a plurality of dielectric layers and at least an inner circuit layer disposed between two adjacent dielectric layers.

The method of fabricating the substrate bumps of high distribution density on the package substrate according to the present invention satisfies the high integration requirement of packaging. Furthermore, in the present invention, the location at which the substrate bumps are formed and the shape of the substrate bumps are taken into consideration, and therefore the solder mask layer is disposed outside the corresponding region occupied by the substrate bumps. As such, unsatisfactory reliability issues arisen from thermal expansion of the solder mask layer is avoided.

In order to make the aforementioned features and advantages of the present invention more comprehensible, several embodiments and associated figures are described in details below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional package substrate.

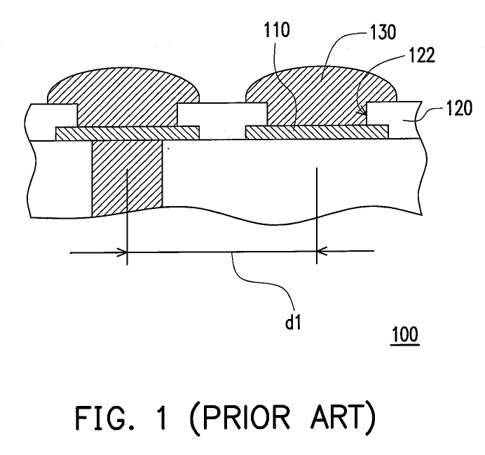

FIG. 2A is a schematic top view of a package substrate according to a first embodiment of the present invention.

FIG. 2B is a schematic cross-sectional view illustrating the package substrate of FIG. 2A along a sectional line I-I′.

FIGS. 3A through 3I are process flow diagrams schematically illustrating a method of fabricating the package substrate depicted in FIG. 2B.

FIG. 4 is a schematic view illustrating the package substrate that is depicted in FIG. 2B and applied to a chip package structure.

FIG. 5A is a schematic top view of a package substrate according to a second embodiment of the present invention.

FIG. 5B is a schematic cross-sectional view illustrating the package substrate depicted in FIG. 5A along a sectional line II-II′.

FIG. 6A is a schematic top view of a package substrate according to a third embodiment of the present invention.

FIG. 6B is a schematic cross-sectional view illustrating the package substrate depicted in FIG. 6A along a sectional line III-III′.

### DESCRIPTION OF EMBODIMENTS

### First Embodiment

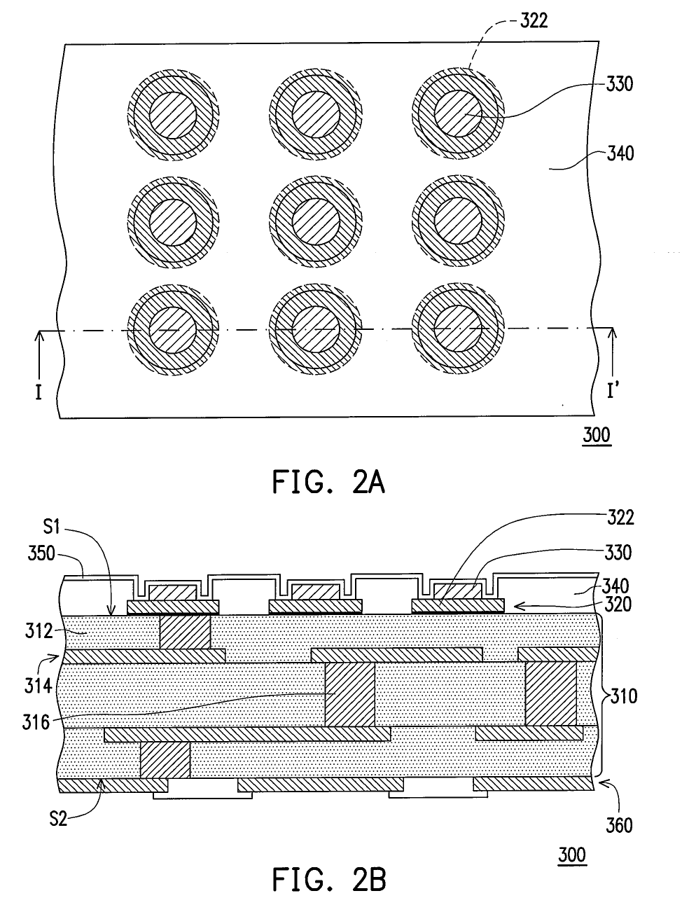

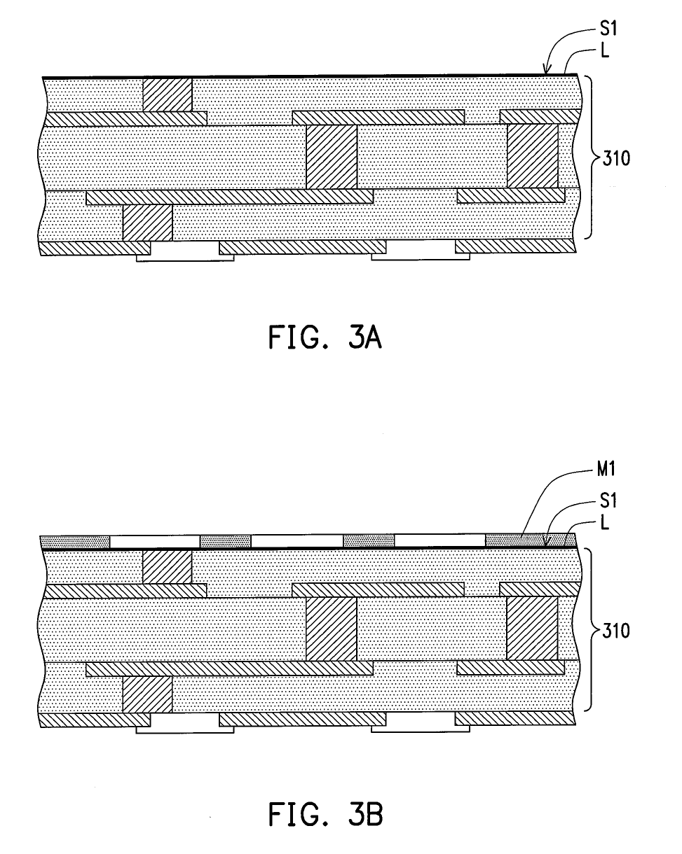

FIG. 2A is a schematic top view of a package substrate according to a first embodiment of the present invention. FIG. 2B is a schematic cross-sectional view illustrating the package substrate depicted in FIG. 2A along a sectional line I-I′. Referring to FIGS. 2A and 2B, a package substrate 300 provided by the first embodiment includes a base layer 310, a surface circuit layer 320, a plurality of conductive bumps 330, and a patterned solder mask layer 340. The surface circuit layer 320 having a plurality of bonding pads 322 is disposed on a surface S1 of the base layer 310. The conductive bumps 330 are disposed on the bonding pads 322 individually to serve as substrate bumps. In addition, the patterned solder mask layer 340 is disposed on the surface S1 of the base layer 310 and outside a corresponding region occupied by the conductive bumps 330, so as to expose the conductive bumps 330.

In the first embodiment, the conductive bumps 330 include a plurality of metal posts, and the material used for the conductive bumps 330 includes copper. Additionally, the package substrate 300 further includes an OSP layer 350 (not shown in FIG. 2A) disposed on surfaces of the conductive bumps 330 and surfaces of the bonding pads 322. The OSP layer 350 prevents the conductive bumps 330 and the bonding pads 322 from being oxidized by exposure to the ambient air, thereby extending the preservation period of the fabricated conductive bumps 330. Before a subsequent flip-chip bonding process is performed on the package substrate 300 and a chip, the package substrate 300 is pre-heated to evaporate the OSP layer 350.

In the first embodiment, the base layer 310 of the package substrate 300 includes a plurality of dielectric layers 312, at least an inner circuit layer 314, and a plurality of conductive vias 316. Here, two inner circuit layers 314 are schematically illustrated in FIG. 2B. Besides, the package substrate 300 further includes another surface circuit layer 360. Each of the inner circuit layers 314 is disposed between two adjacent dielectric layers 312, while the surface circuit layer 360 is disposed on another surface S2 corresponding to the surface S1 of the base layer 310. Besides, each of the conductive vias 316 passes through one of the dielectric layers 312. One of the conductive vias 316 electrically connects the surface circuit layer 320 and the adjacent inner circuit layer 314. Another one of the conductive vias 316 electrically connects the inner circuit layers 314. Besides, still another one of the conductive vias 316 electrically connects the surface circuit layer 360 and the adjacent inner circuit layer 314.

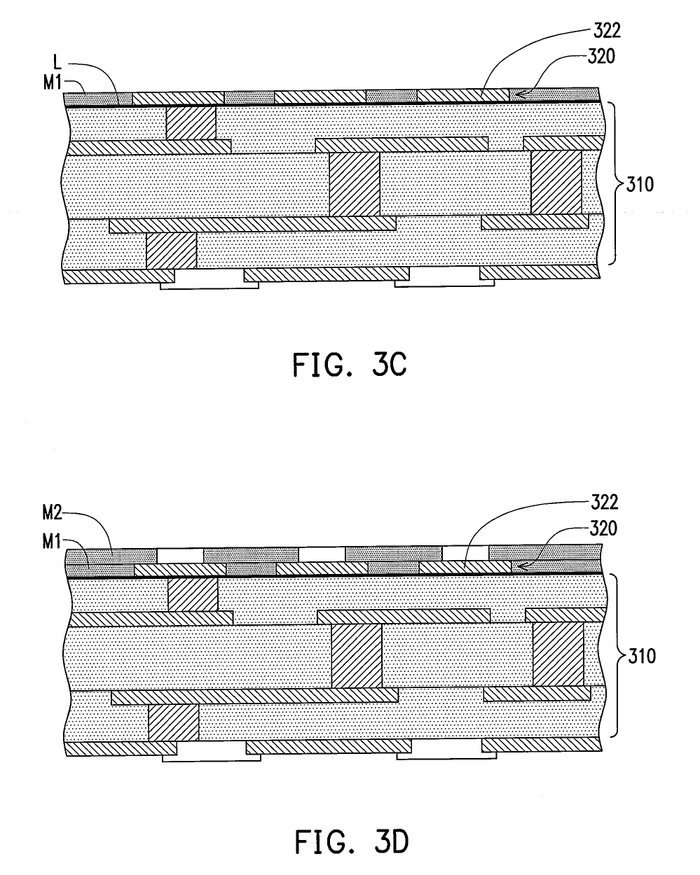

FIGS. 3A through 31 are process flow diagrams schematically illustrating a method of fabricating the package substrate depicted in FIG. 2B. First, referring to FIG. 3A, the base layer 310 is provided. Next, an electroplating seed layer L is formed on the surface S1 of the base layer 310 by, for example, performing a sputtering process.

Thereafter, referring to FIG. 3B, the surface S1 of the base layer 310 is covered by a first patterned mask layer M1, which exposes a portion of the electroplating seed layer L. Note that the first patterned mask layer M1 is formed by forming a dry film photoresist entirely on the surface S1 in advance and then performing a photolithography process on the dry film photoresist.

Afterwards, referring to FIG. 3C, an electroplating process is performed to form the surface circuit layer 320 on the electroplating seed layer L exposed by the first patterned mask layer M1. Here, the surface circuit layer 320 includes a plurality of the bonding pads 322.

Next, as shown in FIG. 3D, the first patterned mask layer M1 and the surface circuit layer 320 are covered by a second patterned mask layer M2, which exposes at least a portion of each of the bonding pads 322. It should be noted that the second patterned mask layer M2 is formed by forming the dry film photoresist entirely on the first patterned mask layer M1 and the surface circuit layer 320 and then performing the photolithography process on the dry film photoresist.

Referring to FIG. 3E, the electroplating process is then performed to form a plurality of the conductive bumps 330 on the bonding pads 322, which are exposed by the second patterned mask layer M2. After that, as shown in FIGS. 3E and 3F, the first patterned mask layer M1 and the second patterned mask layer M2 are removed. The first patterned mask layer M1 and the second patterned mask layer M2 may be removed by employing sodium hydroxide solution or organic solvent, given that the first patterned mask layer M1 and the second patterned mask layer M2 are dry film photoresist.

Afterwards, referring to FIGS. 3F and 3G, the electroplating seed layer L outside the surface circuit layer 320 is removed. Note that the electroplating seed layer L outside the surface circuit layer 320 is removed by implementing the following steps. First, a third patterned mask layer (not shown) exposing the electroplating seed layer L outside the surface circuit layer 320 is formed on the surface circuit layer 320 in advance. Next, the electroplating seed layer L exposed outside the third patterned mask layer is removed through implementing an etching process. The third patterned mask layer is then removed.

Thereafter, referring to FIG. 3H, the patterned solder mask layer 340 is formed on the surface S1 of the base layer 310, and the patterned solder mask layer 340 exposes the conductive bumps 330. It should be noted that the method of forming the patterned solder mask layer 340 includes forming a solder mask material layer (not shown) on the surface S1 of the base layer 310 in advance, such that the solder mask material layer covers the surface circuit layer 320 and the conductive bumps 330. A patterning process (photolithography process) is then performed on the solder mask material layer, so as to remove the solder mask material layer corresponding to the conductive bumps 330, thereby forming the patterned solder mask layer 340. The fabrication of the package substrate 300 is then completed.

Next, referring to FIG. 3I, a surface treatment can be applied to the conductive bumps 330 and the bonding pads 322. For example, the OSP layer 350 may be formed on the surfaces of the conductive bumps 330 and the surfaces of the bonding pads 322. Moreover, in another embodiment, the lead-free surface treatment applied to the package substrate 300 not only includes the formation of the common OSP layer 350, but also comprises an electroless nickel-immersion gold (ENIG) treatment, an immersion silver (ImAg) treatment, an immersion tin (ImSn) treatment, and a hot-air solder leveling (HASL) treatment. The surface treatment to be used is determined based on the designer's demand.

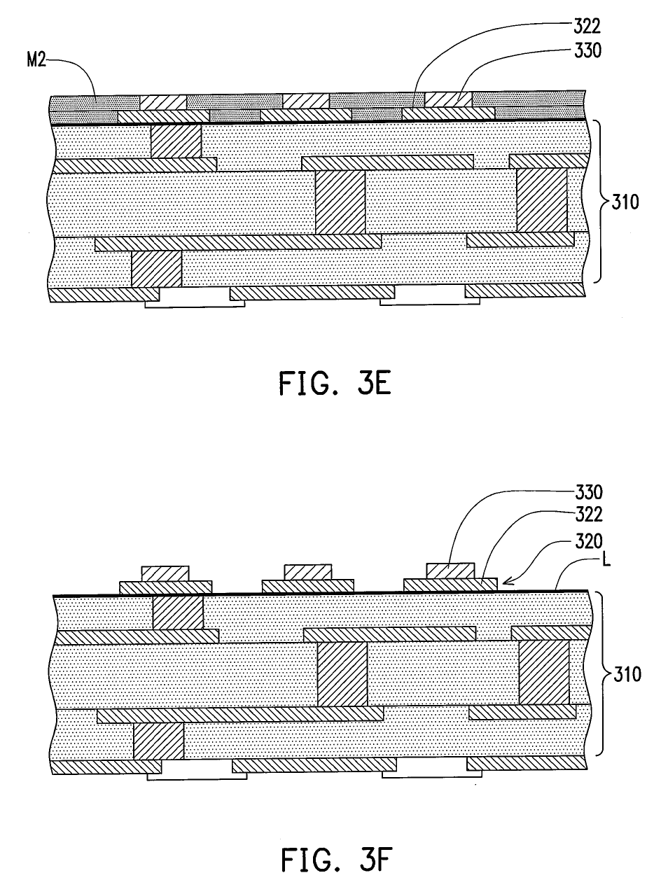

FIG. 4 is a schematic view illustrating the package substrate depicted in FIG. 2B and applied to a chip package structure. A chip package structure 30 includes a chip 32, the package substrate 300, and a plurality of chip bumps 34. The chip 32 is disposed on the surface circuit layer 320 of the package substrate 300, and a plurality of chip pads 32a is disposed on a surface S3 of the chip 32 that faces the surface circuit layer 320. In addition, the chip bumps 34 are correspondingly connected between the chip pads 32a and the conductive bumps 330, such that the chip 32 is electrically connected to the package substrate 300. Moreover, solder balls 36 are disposed at a side of the base layer 310 that is away from the chip 32, so as to electrically connect an electronic device (not shown) of the next level.

Note that the chip bumps 34 are not in contact with the patterned solder mask layer 340. Specifically, the chip bumps 34 and the patterned solder mask layer 340 are disposed with a certain distance in between them.

### Second Embodiment

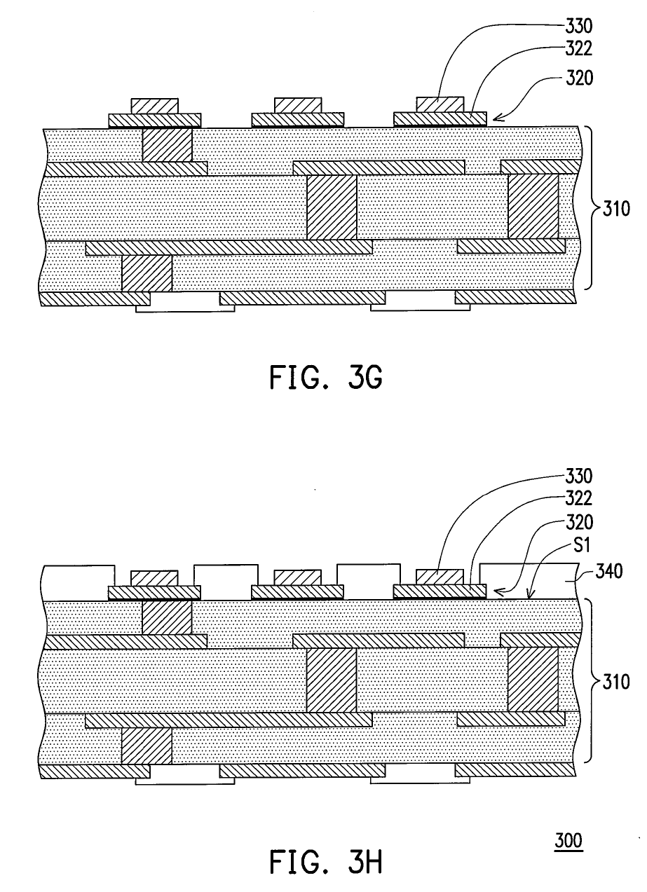

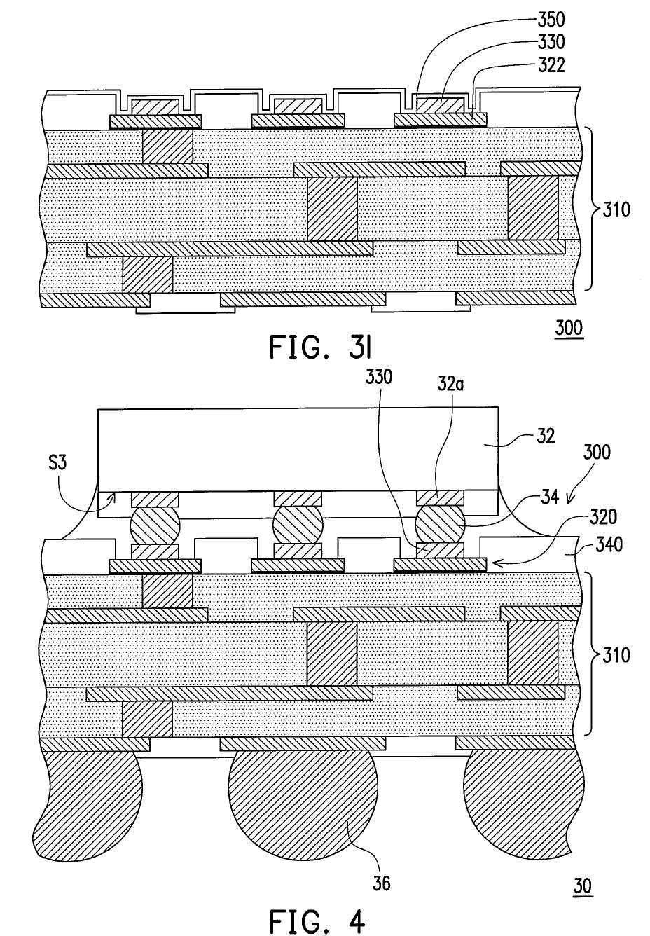

FIG. 5A is a schematic top view of a package substrate according to a second embodiment of the present invention. FIG. 5B is a schematic cross-sectional view illustrating the package substrate depicted in FIG. 5A along a sectional line II-II′. Referring to FIGS. 5A and 5B, the difference between a package substrate 400 provided by the second embodiment and the package substrate 300 discussed in the first embodiment lies in that a patterned solder mask layer 440 of the package substrate 400 in the second embodiment is further disposed outside the corresponding region occupied by bonding pads 422, so as to expose the bonding pads 422 and conductive bumps 430 disposed thereon.

### Third Embodiment

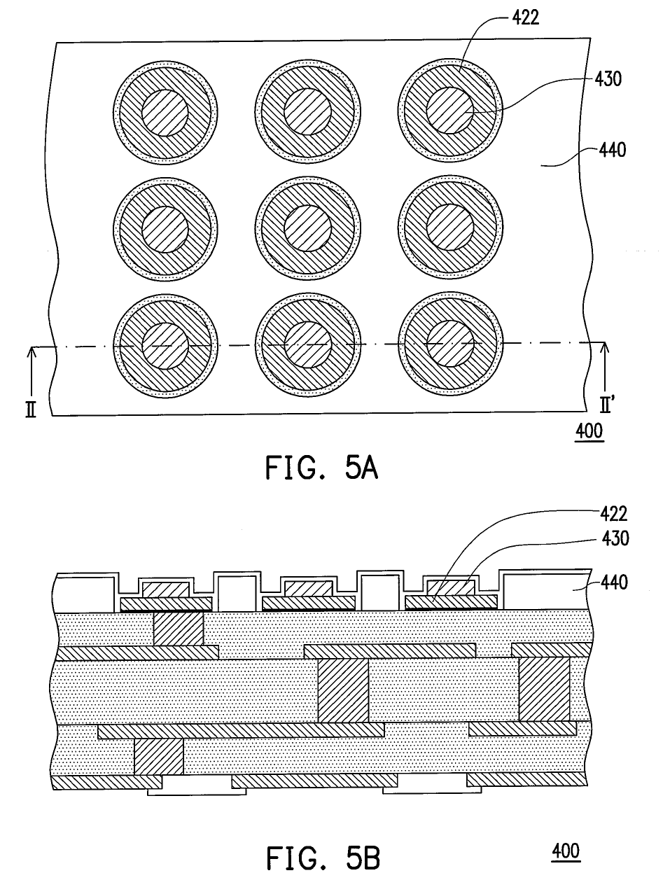

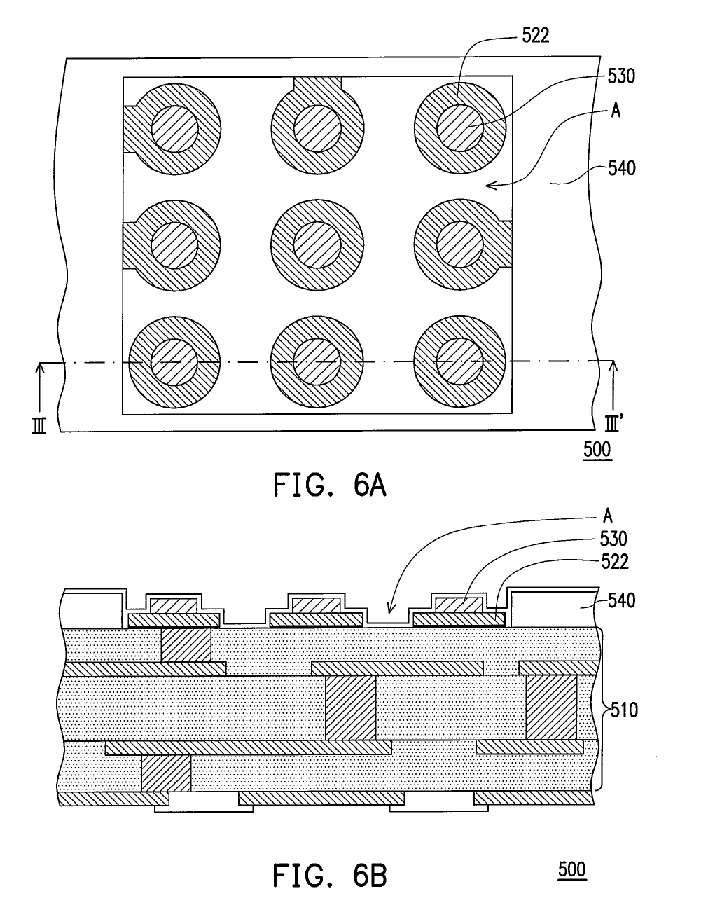

FIG. 6A is a schematic top view of a package substrate according to a third embodiment of the present invention. FIG. 6B is a schematic cross-sectional view illustrating the package substrate depicted in FIG. 6A along a sectional line III-III′. Referring to FIGS. 6A and 6B, the difference between a package substrate 500 provided by the present embodiment and the package substrates 300 and 400 discussed in the previous embodiments lies in that a solder mask layer 540 exposes the entire region of bonding pads 522 and conductive bumps 530 (a region bonding to the chip). In detail, the package substrate 500 has a chip bonding region A on a base layer 510. The bonding pads 522 and the conductive bumps 530 disposed thereon are arranged in arrays in the chip bonding region A, while the patterned solder mask layer 540 exposes the chip bonding region A. The design of the solder mask layer according to the second embodiment and the third embodiment more or less contributes to reducing the amount of the solder mask material used and the complexity of photomasks adopted in the manufacturing process of the solder mask layer. Therefore, the manufacturing costs are further decreased, and the manufacturing process is simplified.

To sum up, the package substrate, the method of fabricating the same, and the chip package structure provided by the present invention at least have the following features and advantages:

The conductive bumps are formed by implementing the electroplating process in the present invention. As such, despite the shortened pitches between the adjacent bonding pads, the conductive bumps can still be accurately formed on the corresponding bonding pads, thus complying with the high integration requirement of packaging.

After the formation of the bonding pads, the conductive bumps serving as the substrate bumps are formed at first, and the solder mask layer is then constructed in the present invention. Therefore, the solder mask layer is not disposed below the conductive bumps, which effectively prevents problems arisen from thermal expansion of the solder mask layer and improves the reliability of the devices.

The location where the solder mask layer is disposed in the present invention is varied upon the actual design demands. For example, the solder mask layer merely exposes the conductive bumps. In an alternative, the solder mask layer simultaneously exposes the conductive bumps and the bonding pads. Moreover, the solder mask layer may even expose the entire chip bonding region of the package substrate. As such, the manufacturing process proposed in the present invention is simple, flexible, and conducive to reducing manufacturing costs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package substrate, comprising:
a base layer;
a surface circuit layer disposed on a surface of the base layer and having a plurality of bonding pads;
a plurality of conductive bumps disposed on the bonding pads individually; and
a patterned solder mask layer disposed on the surface of the base layer and outside a corresponding region occupied by the conductive bumps, so as to expose the conductive bumps.

2. The package substrate as claimed in claim 1, wherein the patterned solder mask layer is further disposed outside a corresponding region occupied by the bonding pads, so as to expose the bonding pads.

3. The package substrate as claimed in claim 1, wherein the conductive bumps comprise a plurality of metal posts.

4. The package substrate as claimed in claim 1, wherein the material used for the conductive bumps comprises copper.

5. The package substrate as claimed in claim 1, wherein the base layer has a chip bonding region in which the bonding pads are arranged in arrays.

6. The package substrate as claimed in claim 5, wherein the patterned solder mask layer exposes the chip bonding region.

7. The package substrate as claimed in claim 1, further comprising an organic solderability preservative layer disposed on surfaces of the conductive bumps and surfaces of the bonding pads.

8. The package substrate as claimed in claim 1, wherein the base layer comprises a plurality of dielectric layers and at least an inner circuit layer disposed between two adjacent dielectric layers.

9. A method of fabricating a package substrate, the method comprising:
providing a base layer;
forming an electroplating seed layer on a surface of the base layer;
covering the surface of the base layer with a first patterned mask layer, which exposes a portion of the electroplating seed layer;
performing an electroplating process to form a surface circuit layer on the electroplating seed layer, which is exposed by the first patterned mask layer, wherein the surface circuit layer comprises a plurality of bonding pads;
covering the first patterned mask layer and the surface circuit layer with a second patterned mask layer, which exposes at least a portion of each of the bonding pads;
performing the electroplating process to form a plurality of conductive bumps on the bonding pads exposed by the second patterned mask layer;
removing the first patterned mask layer and the second patterned mask layer;
removing the electroplating seed layer outside the surface circuit layer;
forming a patterned solder mask layer on the surface of the base layer, and the patterned solder mask layer exposes the conductive bumps.

10. The method of fabricating the package substrate as claimed in claim 9, wherein the method of forming the patterned solder mask layer comprises:
forming a solder mask material layer on the surface of the base layer, such that the solder mask material layer covers the surface circuit layer and the conductive bumps; and
performing a patterning process on the solder mask material layer, so as to remove
the solder mask material layer corresponding to the conductive bumps.

11. The method of fabricating the package substrate as claimed in claim 10, wherein the patterning process comprises performing a photolithography process on the solder mask material layer.

12. The method of fabricating the package substrate as claimed in claim 9, wherein the bonding pads are further exposed by the patterned solder mask layer.

13. The method of fabricating the package substrate as claimed in claim 9, wherein the base layer has a chip bonding region in which the bonding pads are arranged in arrays.

14. The method of fabricating the package substrate as claimed in claim 13, wherein the chip bonding region is further exposed by the patterned solder mask layer.

15. The method of fabricating the package substrate as claimed in claim 9, further comprising conducting a surface treatment to the conductive bumps and the bonding pads after the formation of the patterned mask layer.

16. The method of fabricating the package substrate as claimed in claim 15, wherein the surface treatment comprises forming an organic solderability preservative layer on surfaces of the conductive bumps and surfaces of the bonding pads.

17. The method of fabricating the package substrate as claimed in claim 9, wherein the first patterned mask layer or the second patterned mask layer comprises a dry film photoresist.

18. A chip package structure, comprising:
a base layer;
a surface circuit layer disposed on a surface of the base layer and having a plurality of bonding pads;
a plurality of conductive bumps disposed on the bonding pads individually;
a patterned solder mask layer disposed on the surface of the base layer and outside a corresponding region occupied by the conductive bumps, so as to expose the conductive bumps;
a chip disposed on the surface circuit layer, wherein a plurality of chip pads is disposed on a surface of the chip, and the surface of the chip faces the surface circuit layer; and
a plurality of chip bumps, which correspondingly connect the chip pads and the conductive bumps.

19. The chip package structure as claimed in claim 18, further comprising a plurality of solder balls disposed at a side of the base layer, wherein the side of the base layer is away from the chip.
